(19) United States
(12) Patent Application Publication
(10) Pub. No.: US 2025/0176416 A1
(43) Pub. Date: May 29, 2025

(54) ORGANIC OPTOELECTRONIC DEVICE WITH MICROLENS ARRAYS

(71) Applicant: The Regents of the University of Michigan, Ann Arbor, MI (US)

(72) Inventors: Stephen R. Forrest, Ann Arbor, MI (US); Claire Arneson, Ann Arbor, MI (US); Hafiz Sheriff, Ann Arbor, MI (US)

(21) Appl. No.: 18/956,871

(22) Filed: Nov. 22, 2024

Related U.S. Application Data
(60) Provisional application No. 63/602,831, filed on Nov. 27, 2023.

(51) Int. Cl. H10K 59/80; H10K 71/00

(52) U.S. Cl. CPC H10K 59/8791; H10K 59/879; H10K 71/621

(57) ABSTRACT

An organic light emitting device (OLED), comprising a substrate layer, an external microlens array positioned below the substrate layer, a graded antireflective coating on a surface of the external microlens array opposite the substrate layer, a first electrode layer positioned over the substrate layer, a light emitting layer positioned over the first electrode layer, and a second electrode layer positioned over the light emitting layer. Also described herein is a method of manufacturing an organic light emitting device.

### CROSS-REFERENCE TO RELATED APPLICATIONS

This application claims priority to U.S. Provisional Application No. 63/602,831, filed on Nov. 27, 2023, incorporated herein by reference in its entirety.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety. One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)₃, which has the following structure:

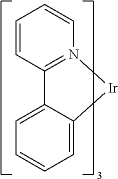

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, on a conventional energy level diagram, with the vacuum level at the top, a “shallower” energy level appears higher, or closer to the top, of such a diagram than a “deeper” energy level, which appears lower, or closer to the bottom.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

Phosphorescent OLEDs can achieve nearly 100% internal quantum efficiency (IQE). A typical OLED's efficiency on a planar glass substrate is about 20% for Ir(ppy)2 acac, which has IQE ˜88%. Some of the light is lost to SPP modes (surface plasmon polariton). The use of an index-matching fluid (IMF) indicates a potential increase in efficiency. The index of glass (1.5) relative to air (1) results in reflection at the glass/air interface. An IMF eliminates this interface.

Designs for decreasing the index of refraction mismatch are material limited. Sapphire substrates, for example, achieve this but are prohibitively expensive. Planarization is not used for gratings or random nanostructures which could introduce issues in the organic stack.

External microlens arrays (MLAs) are currently used with organic light emitting diodes (OLEDs) to increase outcoupling efficiency by extracting light trapped in substrate modes. In any OLED structure, light can be coupled into air, or trapped within the device in the form of surface plasmon-polariton, waveguide, or substrate modes. Substrate modes arise from the index mismatch between the bottom contact/substrate interface and the substrate/air interface causing internal reflection and preventing light from being outcoupled. The outcoupling efficiency can be increased by coupling substrate modes into air modes by decreasing the index mismatch between the substrate and air, or by increasing the incidence angle of light reaching the substrate/air interface. The geometry of an MLA increases the coupling from substrate modes into air modes by modifying the planar glass surface and decreasing the fraction of light reflected into the substrate at the substrate/air interface.

Thus, there is a need in the art for improved organic optoelectronic devices having increased efficiency and light outcoupling by using MLAs and other design techniques.

### SUMMARY OF THE INVENTION

In one aspect, an organic light emitting device (OLED) comprises a substrate layer, an external microlens array positioned below the substrate layer, a graded antireflective coating on a surface of the external microlens array opposite the substrate layer, a first electrode layer positioned over the substrate layer, a light emitting layer positioned over the first electrode layer, and a second electrode layer positioned over the light emitting layer.

In some embodiments, the light emitting layer comprises a first organics sublayer, an EML-organics sublayer positioned over the first organics sublayer, and a second organics sublayer positioned over the EML-organics sublayer. In some embodiments, the external microlens array comprises a hexagonal-close packed array of hemispherical lenses. In some embodiments, the graded antireflective coating comprises a low refractive index material. In some embodiments, the graded antireflective coating comprises porous Teflon, Teflon or silicon dioxide. In some embodiments, the external microlens array is adjacent to the substrate layer. In some embodiments, the graded antireflective coating includes low-index layers configured such that the index of the microlens array MLA is graded to match the index of air. In some embodiments, the external microlens array has an index of refraction of 1.4 to 1.5.

In some embodiments, the device has an outcoupling efficiency of 30% to 40%. In some embodiments, the device has an enhancement factor of 1.6 to 1.7. In some embodiments, the graded antireflective coating comprises a 100 nm to 125 nm thick first coating with an index of refraction of 1.3 to 1.35, a 125 nm to 135 nm thick second coating below the first coating with an index of refraction of 1.15 to 1.25, and a 145 nm to 155 nm thick third coating below the second coating with an index of refraction of 1.0 to 1.1. In some embodiments, the device has an outcoupling efficiency of 40% to 50%. In some embodiments, the device has an enhancement factor of 1.75 to 1.85. In some embodiments, the device has one or more characteristics selected from the group consisting of being flexible, being rollable, being foldable, being stretchable, being curved, being transparent, and being semi-transparent. In some embodiments, the light emitting layer is configured to produce light via at least one of phosphorescence, fluorescence, thermally activated delayed fluorescence (TADF), phosphorescent delayed fluorescence, and triplet-triplet annihilation.

In some embodiments, the device comprises a 90 nm to 110 nm thick Al cathode, a 50 nm to 70 nm thick electron transport layer below the cathode with an index of refraction of 1.6 to 1.8, a 20 nm to 40 nm thick light emitting layer below the electron transport layer, a 20 nm to 30 nm thick hole transport layer below the light emitting layer with index of refraction of 1.6 to 1.8, a 140 nm to 160 nm thick ITO anode below the hole transport layer, and a semi-infinite microlens array below the anode with index of refraction of 1.4 to 1.5. In some embodiments, the graded reflective coating has a refractive index selected from the group consisting of: less than 1.35, less than 1.3, less than 1.25, less than 1.2, less than 1.15, less than 1.10, and less than 1.05. In some embodiments, the graded reflective coating is two or more layers of graded reflective coating. In some embodiments, a first layer and a second layer of the two or more layers are made of different materials, and wherein the first layer is closer to the external microlens array than the second layer and where in the first layer has a higher refractive index than the second layer. In some embodiments, at least one layer of the two or more layers has a refractive index between 1.05 and 1.3.

In another aspect, a method of manufacturing an organic light emitting device (OLED), comprises providing a substrate layer, etching a sub-electrode microlens array (SEMLA) into the substrate layer, depositing a first electrode layer over the substrate layer, depositing a light emitting layer over the first electrode layer, and depositing a second electrode layer over the light emitting layer. In some embodiments, the method further comprises depositing a distributed Bragg reflector (DBR) layer over the substrate layer prior to depositing the first electrode layer over the substrate layer. In some embodiments, the method further comprises depositing a Purcell Factor (PF) enhancement layer over the second electrode layer. In some embodiments, the method further comprises deposing a graded antireflective coating on a surface of the external microlens array opposite the substrate layer.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 shows an organic light emitting device.

FIG. 2 shows an inverted organic light emitting device that does not have a separate electron transport layer.

FIG. 3 shows a structure of an OLED with an external microlens array (MLA) and an anti-reflection coating.

FIG. 4 shows a graph of transmission through an MLA hexagonal-close packed array of hemispherical lenses 10 μm in diameter vs. MLA index. Transmission is calculated using geometric ray tracing.

FIG. 5 shows a graph of coupling efficiency for a 620 nm OLED vs. electron transporting layer (ETL) thickness.

FIG. 6 shows a graph of external quantum efficiency for various green phosphorescent OLEDs.

FIG. 7 is a graph of index of refraction vs. wavelength for porous Al₂O₃ films.

FIG. 8 is a graph of the angle dependent reflectance vs. wavelength for neat PMMA films with no coating, a single later quarter wavelength coating, and a 3-layer graded index coating.

FIG. 9A is an image of a cross-sectional view of porous Teflon coating PMMA on glass as viewed though a scanning electron microscope.

FIG. 9B is image of a top-down view of porous Teflon coating PMMA on glass as viewed through a scanning electron microscope.

FIG. 10 is a flowchart depicting a method of manufacturing an organic light emitting device (OLED).

### DETAILED DESCRIPTION

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

In some aspects of the present invention, software executing the instructions provided herein may be stored on a non-transitory computer-readable medium, wherein the software performs some or all of the steps of the present invention when executed on a processor.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

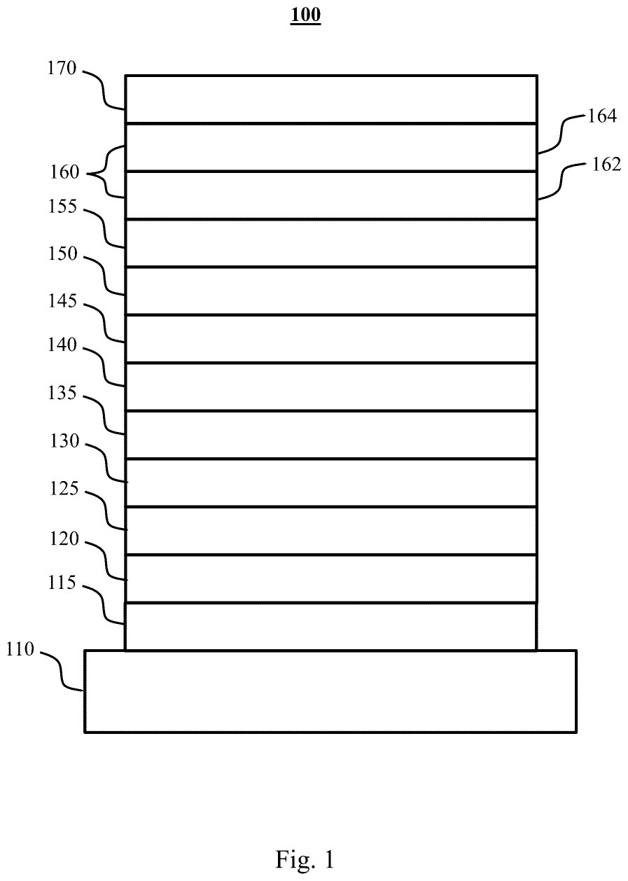

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

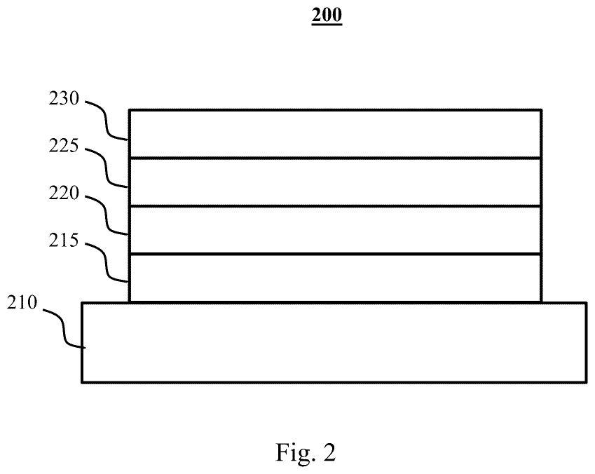

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theaters or stadium screens, light therapy devices, and signs. Various control mechanisms may be used to control devices fabricated in accordance with the present disclosure, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

Although certain embodiments of the disclosure are discussed in relation to one particular device or type of device (for example OLEDs) it is understood that the disclosed improvements to light outcoupling properties of a substrate may be equally applied to other devices, including but not limited to PLEDs, OPVs, charge-coupled devices (CCDs), photosensors, or the like.

Although exemplary embodiments described herein may be presented as methods for producing particular circuits or devices, for example OLEDs, it is understood that the materials and structures described herein may have applications in devices other than OLEDs. For example, other optoelectronic devices such as organic solar cells and organic photodetectors may employ the materials and structures. More generally, organic devices, such as organic transistors, or other organic electronic circuits or components, may employ the materials and structures.

In some embodiments, the OLED has one or more characteristics selected from the group consisting of being flexible, being rollable, being foldable, being stretchable, and being curved.

In some embodiments, the OLED is transparent or semi-transparent. In some embodiments, the OLED further comprises a layer comprising carbon nanotubes.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layers can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

Currently, MLAs are used with both bottom-emitting and top-emitting OLEDs and can be combined with other outcoupling structures such as sub-electrode microlens arrays (SEMLA). The enhancement factor (EF), defined as the ratio of outcoupling efficiency for an OLED with and without outcoupling enhancement structures, achieved with MLAs is 1.49 for bottom-emitting OLEDs, 1.51 for top-emitting OLEDs, and 1.9 when combined with SEMLA for bottom emitting OLEDs (see Sun, Y., et al., Journal of applied physics, 2006; Thomschke, M., et al., Nano letters, 2012; and Qu, Y., et al., ACS photonics, 2018). In laboratory-scale applications, index-matching fluid (IMF) can be used to couple nearly 100% of substrate modes into air modes, achieving EF=2.8 when combined with SEMLA. To increase the efficiency of MLA outcoupling such that it can approach values achieved by IMF, two schemes may be utilized. In the first scheme, the MLA has an index approximately equal to or higher than the substrate index, and the index mismatch between air and MLA is decreased. In the second scheme, the MLA is composed of a material with an index matching that of air, and the index mismatch between the substrate and MLA is decreased.

The present disclosure focuses on the first approach because of the ubiquity of high-index polymers that can be used to construct MLAs, compared to the rarity of low-index materials suitable for applications over a large area. Both conditions of the first approach are satisfied by combining MLA structures with a minimum index of n=1.45, which is an approximate match to the index of glass, and low-index anti-reflection coatings (ARC) which are in some embodiments designed using a genetic algorithm and transfer matrix formalism.

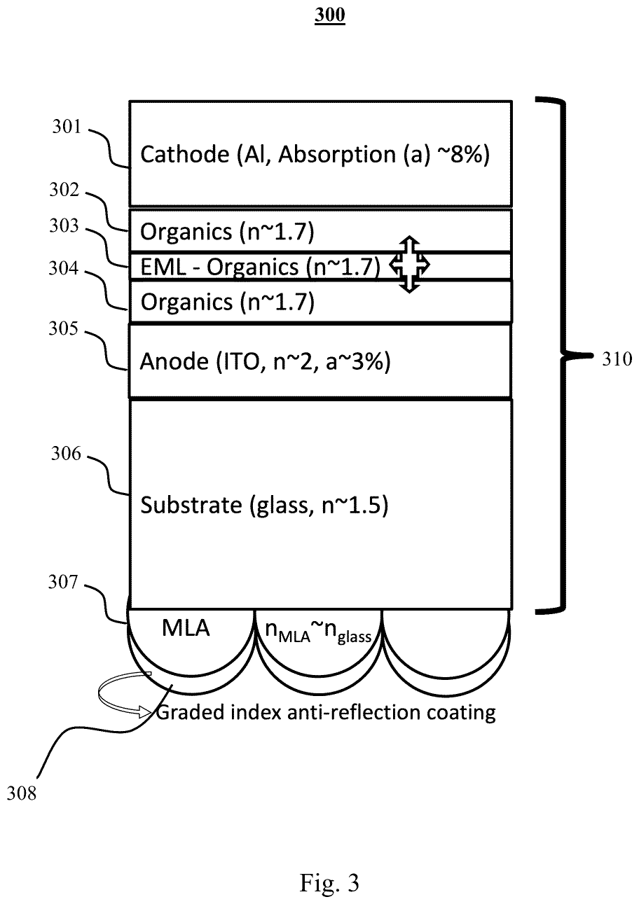

Referring now to FIG. 3 shown is the structure of an organic light emitting device (OLED) 300 comprising a substrate layer 306, a first electrode layer 305 positioned above the substrate layer, a light-emitting layer positioned over the substrate layer, a second electrode layer 301 positioned above the light-emitting layer, a microlens array 307 position below the substrate layer 305, and a graded anti-reflection coating 308 positioned on the outward-facing surface of the microlens array 307.

In some embodiments, the light-emitting layer comprises a first organics sublayer 304, an emissive-organics (EML) sublayer 303 positioned over the first organics sublayer 304, and a second organics sublayer 302 positioned over the emissive organics sublayer 303. In some embodiments, the light-emitting layer has a thickness ranging between 20 nm and 40 nm. In some embodiments, the light-emitting layer is configured to produce light via at least one phosphorescence, fluorescence, thermally activated delayed fluorescence (TADF), a phosphorescent delayed fluorescence, and triplet-triplet annihilation.

In some embodiments, the second electrode layer 301 is a cathode. In some embodiments, the second electrode layer comprises aluminum (Al). In some embodiments, the second electrode layer has a thickness ranging between 90 nm and 110 nm. In some embodiments, the OLED 300 further comprises an electron transport layer positioned below the second electrode layer, for example between the second electrode 301 and the EML layer 303. In some embodiments, the electron transport layer has a thickness ranging between 50 nm and 70 nm. In some embodiments, the electron transport layer has an index of refraction between 1.6 and 1.8.

In some embodiments, the first electrode layer 305 is an anode. In some embodiments, the first electrode layer 305 comprises a transparent or semi-transparent conductive material, for example indium tin oxide (ITO). In some embodiments, the first electrode layer 305 may have a thickness ranging between 140 nm and 160 nm. In some embodiments, a hole transport layer may be positioned below the light emitting layer and over the first electrode layer 305. In some embodiments, the hole transport layer has a thickness ranging between 20 nm and 30 nm. In some embodiments, the first hole transport layer has an index of refraction between 1.6 and 1.8.

In some embodiments, the microlens array 307 is positioned adjacent to the substrate layer 306. In some embodiments, the microlens array 307 may have a refractive index equal to or approximately equal to the refractive index of the adjacent substrate. In some embodiments, the microlens array 307 may comprise the same material as the adjacent substrate. In some embodiments, a difference between a refractive index of the substrate 306 and the microlens array 307 may be less than 0.4, less than 0.35, less than 0.3, less than 0.25, less than 0.2, less than 0.15, less than 0.1, less than 0.05, or less than 0.01.

In some embodiments, the microlens array 307 may be fabricated using traditional molding methods (see Sun, Y., et al., Journal of applied physics, 2006; and Möller, S., et al., Journal of Applied Physics, 2002.) In some embodiments, the microlens array 307 comprises a hexagonal-close packed array of hemispherical lenses (see Qu, Y., et al., ACS photonics, 2018).

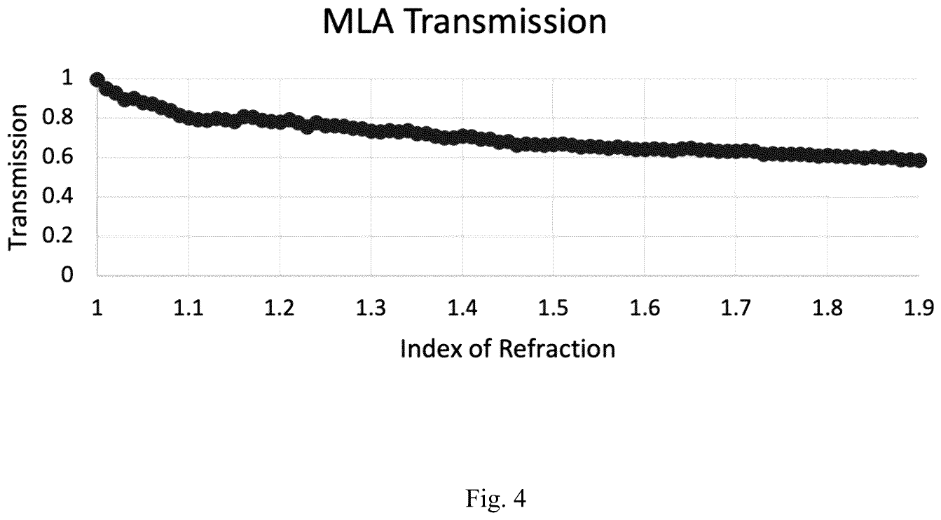

In some embodiments, ray tracing simulations may be used to show that the transmission through the microlens array 307 and decreases with increasing MLA index, as is shown in FIG. 4.

In some embodiments, a genetic algorithm and transfer matrix formalism may be used to show that the transmission through the microlens array 307 decreases with increasing MLA index, as is shown in FIG. 4. Next, a genetic algorithm and transfer matrix formalism may be used to design an anti-reflective coating that will reduce reflection at the MLA/air interface (see Sheriff Jr, H. K., et al., Applied Physics Letters, 2021). In some embodiments, the microlens array structure comprises a set of low-index layers extending outward from the MLA, such that a difference in refractive index between the low-index layer closest to the MLA and the refractive index of the MLA is small, and wherein each subsequent low-index layer has a slightly lower refractive index than the previous low-index layer, until the outer-most (i.e. farthest from the MLA) low-index layer has a refractive index close to or equal to the refractive index of air. In some embodiments, a difference in refractive index between adjacent layers in the set of low-index layers is less than 0.4, less than 0.35, less than 0.3, less than 0.25, less than 0.2, less than 0.15, less than 0.1, less than 0.05, or less than 0.01. Next, the anti-reflective coating 308 may be coated onto the microlens array 307 in two or more individual layers. Finally, the OLED 310 is applied to the microlens array 307, either by OLED deposition directly on to the MLA substrate, or by external application of the microlens array 307 to the substrate 306.

In some embodiments, the graded anti-reflective coating 308 comprises a low refractive index material. In some embodiments, the graded anti-reflective coating 308 comprises two or more low refractive index layers configured such that the refractive index of the microlens array 307 is graded to match the refractive index of the MLA on the surface adjacent to the MLA and to match the refractive index of air at the surface exposed to air. In some embodiments, the graded anti-reflective coating comprises porous Teflon, Teflon, or silicon dioxide. In some embodiments, the graded anti-reflective coating 308 has a refractive index selected from the group consisting of: less than 1.35, less than 1.3, less than 1.25, less than 1.2, less than 1.15, less than 1.10, and less than 1.05.

In some embodiments, the graded anti-reflective coating 308 may comprise any number of distinct layers to form the gradation, for example two, three, four, five, six, seven, eight, nine, or ten layers. In some embodiments, the graded anti-refractive coating 308 may comprise only one layer. In some embodiments, the graded anti-refractive coating 308 may comprise two or more layers. In some embodiments, the refractive index n of each layer of the graded anti-refractive coating 308 may decrease as each layer is applied, for example with a first layer having a highest refractive index closest to the surface of the microlens array 307, followed by a second layer with a lower refractive index positioned on the opposite side of the first layer from the microlens array 308, followed by a third layer having a lower refractive index positioned on the opposite side of the second layer from the first layer, etc. In some embodiments, at least one layer of the one or more layers has a refractive index between 1.05 and 1.3. In some embodiments, a difference between refractive indices of adjacent layers may be less than a maximum difference, for example less than 0.4, less than 0.35, less than 0.3, less than 0.25, less than 0.2, less than 0.15, less than 0.1, less than 0.05, or less than 0.01.

In some embodiments, low-index layers for the graded anti-reflective coating 308 may be fabricated through a variety of methods. For example, deposition via vacuum thermal evaporation (VTE) of polymers with organic porogens (see Wang, B. et al. (2019). Nano letters, 19(2), 787-792.), oblique-angle deposition of Teflon or silicone dioxide (see Wang, B. et al. (2017). Optica, 4(2), 239-242.); Sobahan, K. M. A. et al. Optics Communications, 284(3) 873-876.), direct write X-ray or E-beam lithography (see Tu Min et al. Nature Materials 20, no. 1 (2021): 93-99.; Xomalis et al. ACS Applied Nano Materials 6, no. 5 (2023): 3388-3394.), atomic layer deposition (ALD) with metal alkoxide porogens, and solution-processed films with porogens activated by proton exposure (that is, photon lithography).

In some embodiments, the device 300 has an outcoupling efficiency of about 20%, about 25%, about 30%, about 31%, about 32%, about 33%, about 34%, about 35%, about 36%, about 37%, about 38%, about 39%, about 40%, about 41%, about 42%, about 43%, about 44%, about 45%, about 46%, about 47%, about 48%, about 50%, about 55%, about 60%, between 20% and 60%, between 25% and 55%, between 30% and 50%, or between 35%, and 45%.

In some embodiments, the device 300 has an enhancement factor (EF) of about 1.5, about 1.55, about 1.6, about 1.65, about 1.7, about 1.75, about 1.8 about 1.85, about 1.9, between 1.5 and 1.9, between 1.55 and 1.85, between 1.6 and 1.8, between 1.6 and 1.7, between 1.65 and 1.75, or between 1.75 and 1.85.

In some embodiments, the device 300 has one or more characteristics selected from the group consisting of being flexible, being rollable, being foldable, being stretchable, being curved, being transparent, and being semi-transparent.

In some embodiments, the device 300 may be configured as a top-emission device wherein the device comprises a substrate layer, a first electrode layer positioned above the substrate layer, a light emitting layer positioned above the first electrode layer, and a second electrode layer positioned above the light emitting layer, an external microlens array positioned over the second electrode layer, and a graded antireflective coating on a surface of the external microlens array opposite the second electrode layer. In some embodiments, the substrate layer may be opaque.

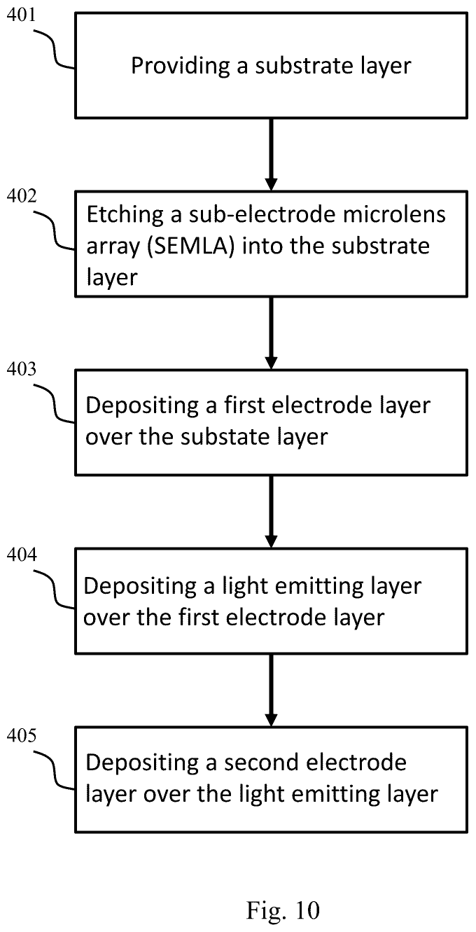

In another aspect, the present disclosure relates to a method of manufacturing an organic light emitting device (OLED). Referring now to FIG. 10, the method 400 comprises providing a substrate layer (401), etching a sub-electrode microlens array (SEMLA) into the substrate layer (402), depositing a first electrode layer over the substrate layer (403), depositing a light emitting layer over the first electrode layer (404), depositing a second electrode layer over the light emitting layer (405).

In some embodiments, the method further comprises depositing a distributed Bragg reflector (DBR) layer over the substrate layer prior to depositing the first electrode layer over the substrate layer. In some embodiments, the method further comprises depositing a Purcell Factor (PF) enhancement layer over the second electrode layer. In some embodiments, the method further comprises depositing a graded antireflective coating on a surface of the external microlens array opposite the substrate layer.

### Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL

A hole injecting/transporting material to be used in the present disclosure is not particularly limited, and any compound may be used as long as the compound is typically used as a hole injecting/transporting material.

### EBL

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, OLEDs and other similar devices may be fabricated using a variety of techniques and devices. For example, in OVJP and similar techniques, one or more jets of material is directed at a substrate to form the various layers of the OLED.

### EXPERIMENTAL EXAMPLES

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the system and method of the present invention. The following working examples therefore, specifically point out the exemplary embodiments of the present invention, and are not to be construed as limiting in any way the remainder of the disclosure.

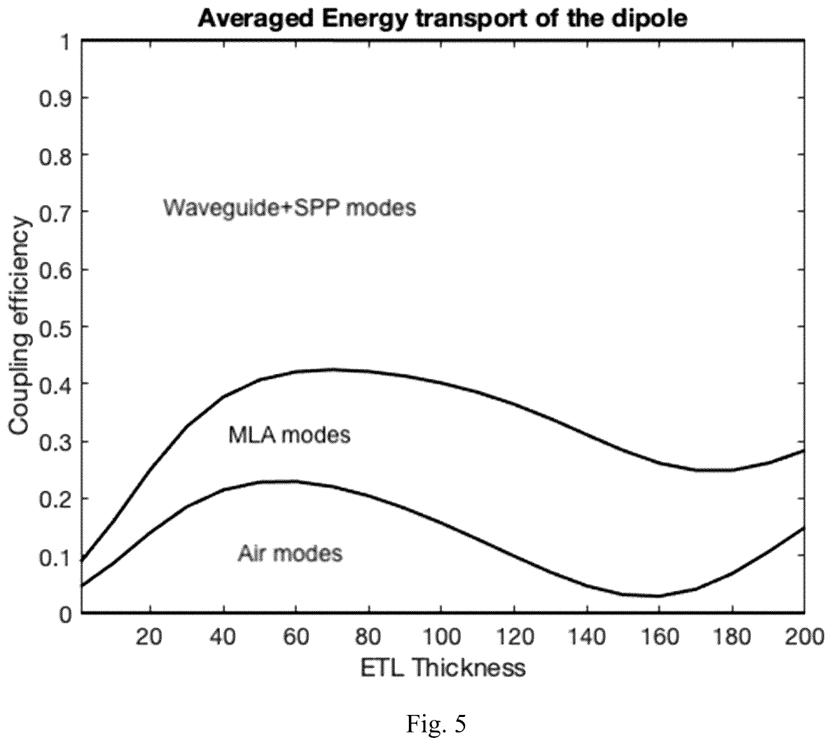

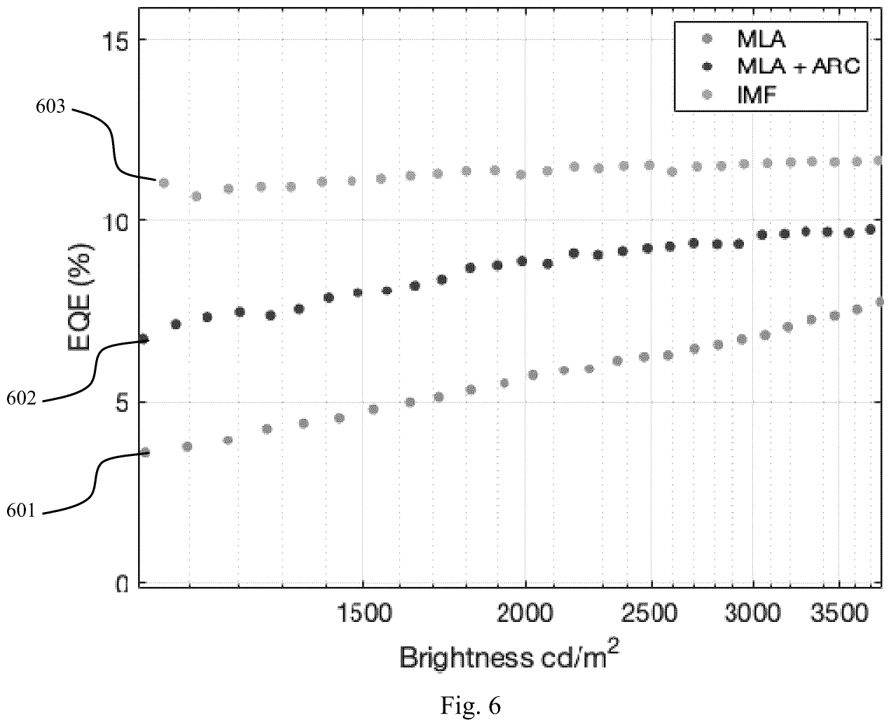

Using Green's function simulations, the fraction of light coupled from a green OLED into an MLA with index n=1.45 was computed. FIG. 5 shows the coupling efficiency into each mode, assuming an MLA index of n_{MLA}=1.45. The simulated OLED emission is 620 nm for the following device structure, where the thickness of the ETL is varied: 100 nm Al cathode/x nm n=1.7 ETL/30 nm emissive layer/25 nm n=1.7 HTL/150 nm ITO anode/semi-infinite n=1.45 MLA. A 60 nm ETL is assumed for the following calculations. The device outcoupling efficiency is equal to the fraction of light coupled into air modes plus the fraction of substrate/MLA modes coupled into air, given by Equation 1 below:

$${η}_{oc} = {η}_{air} + {η}_{sub / MLA} \times T \qquad Equation 1$$

where T is the transmission of MLA+ARC, where transmission is computed using ray tracing. The transmission for an MLA with n_{MLA}=1.45 is T=78%, assuming Lambertian emission. Thus, the outcoupling efficiency is 36%, with EF=1.65. Using a genetic algorithm and transfer matrix formalism, an improved three-layer ARC structure is then designed with the following structure: 117 nm coating with n=1.32/129 nm coating with n=1.2/149 nm coating with n=1.04. With this ARC, T=96%, assuming Lambertian emission from the final layer. resulting in an outcoupling efficiency of 41% with EF=1.8. Preliminary results, shown in FIG. 6, demonstrate EF=1.4 for and MLA with a single layer ¼ wavelength ARC compared to a control MLA with no coating. The graph of FIG. 6 shows results for a first device 601 having an uncoated PMMA microlens array (MLA), a second device 602 having a MLA coated with a ¼ wavelength film of Teflon, and a third device 603 having an index-matching fluid (IMF).

Additional device characteristics are listed below in Table 1.

TABLE 1

| | MLA + ARC | MLA + ARC | | |
|---|---|---|---|---|
| MLA EQE | EF | EQE | IMF EF | IMF EQE |
| 6.8% | 1.40 | 9.5% | 1.21 | 11.58% |
| 6.8% | 1.42 | 9.7% | 1.22 | 11.87% |

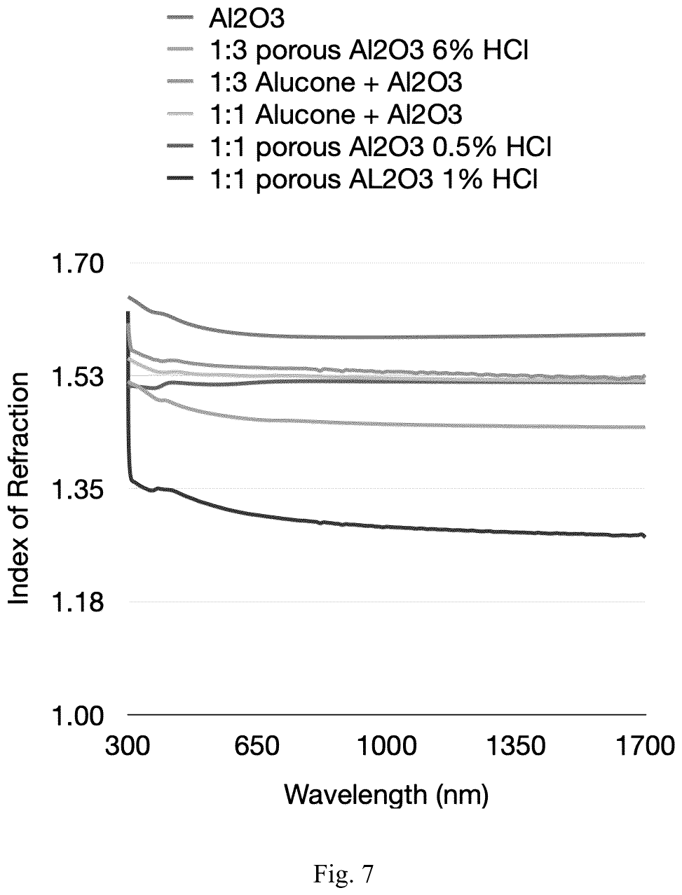

Low-index layers achieving indexes ranging from n˜1.05-1.3 can be fabricated through a variety of methods, including deposition via vacuum thermal evaporation (VTE) of polymers with organic porogens (see Wang, B., et al., Nano letters, 2019), oblique-angle deposition of Teflon or silicon dioxide (see Wang, B., et al., Optica, 2017; and Sobahan, K. M. A., et al., Optics Communications, 2011), direct write X-ray or E-beam lithography (see Tu, Min, et al., Nature Materials, 2021; and Xomalis, A., et al., ACS Applied Nano Materials, 2023), and/or atomic layer deposition (ALD) with metal alkoxide porogens. Both VTE with organic porogens and oblique-angle deposition have achieved published results of n=1.1 and n=1.08, respectively (see Wang, B., et al., Nano letters, 2019; and Wang, B., et al., Optica, 2017). In preliminary experiments, n=1.35, see FIG. 7, has been achieved for porous Al₂O₃ films deposited by ALD. The porous structure is achieved by co-depositing Al₂O₃ with a metal alkoxide porogen, such as Alucone. The metal alkoxide porogen can then be removed from the film using HCl, leaving behind a porous metal oxide. While direct write X-ray and E-beam lithography have been used to fabricate nanosturcures and pores in polymer and organic films, this technology has not yet been used for the purpose of constructing low-index porous films. To realize porous structures using direct write X-ray or E-beam lithography, small pores throughout the bulk film would be exposed by focusing the electron or x-ray source at various depths throughout the film, and exposed areas then removed using a wet etch.

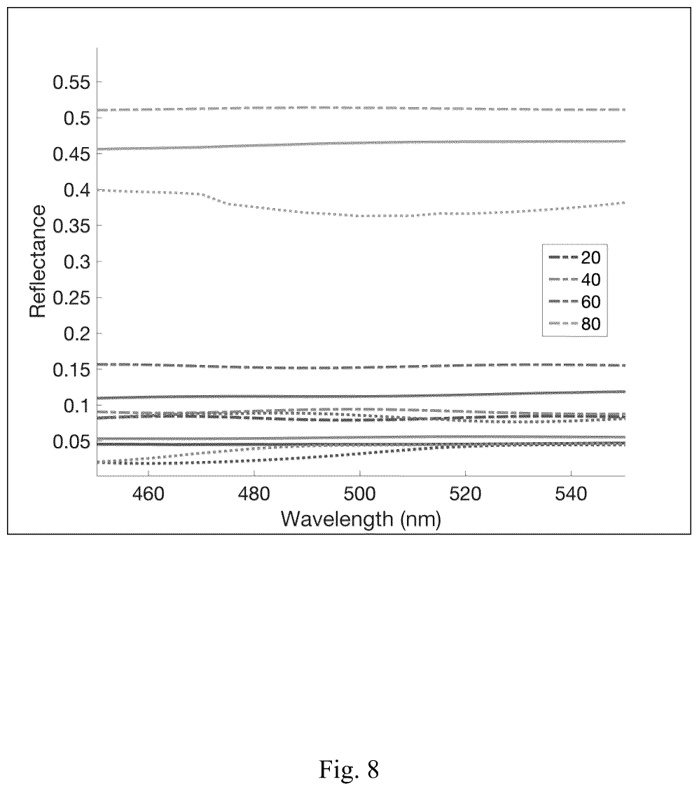

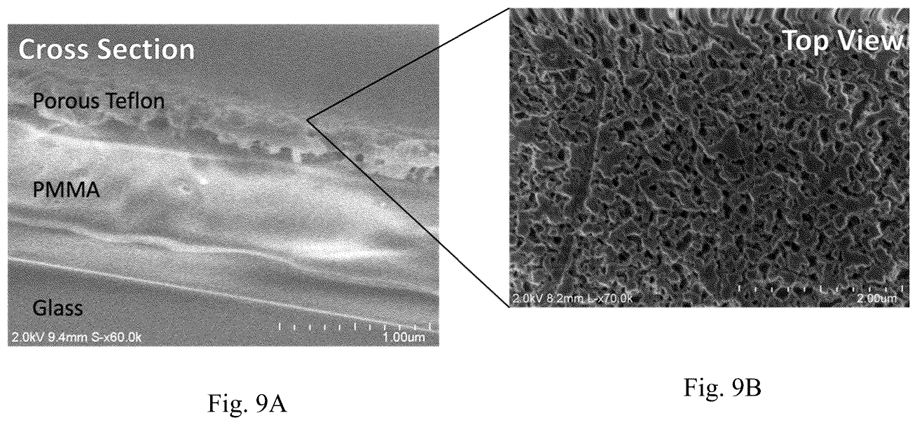

Referring to FIG. 8, shown is a plot showing the results of an experiment characterizing the anti-reflective properties of porous and graded-index porous Teflon on a poly methyl methacrylate (PMMA) film. FIG. 8 shows the angle dependent reflectance versus wavelength of neat PMMA films with no coating (long dashed lines), PMMA coated with a quarter wavelength Teflon (n=1.3) coating (solid lines), and PMMA coated with a 3-layer graded index (n=1.3-1.1) porous Teflon anti-reflection coating (dotted lines). Reflectance is measured from 20° to 80° from the axis normal to the substrate surface. The results demonstrate that the graded index coating reduces reflectance by 30%, and that porous Teflon structure can be fabricated on a polymer surface. The porous surface is shown in FIGS. 9A-9B, depicting scanning electron microscope images of a cross-sectional view (FIG. 9A) and top-down view (FIG. 9B) of porous Teflon coating PMMA on glass.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

### REFERENCES

The following publications are incorporated by reference herein in their entireties:
Sun, Y., & Forrest, S. R. (2006). Organic light emitting devices with enhanced outcoupling via microlenses fabricated by imprint lithography. Journal of applied physics, 100(7), 073106.
Thomschke, M., Reineke, S., Lüssem, B., & Leo, K. (2012). Highly efficient white top-emitting organic light-emitting diodes comprising laminated microlens films. Nano letters, 12(1), 424-428.
Qu, Y., Kim, J., Coburn, C., & Forrest, S. R. (2018). Efficient, nonintrusive outcoupling in organic light emitting devices using embedded microlens arrays. ACS photonics, 5(6), 2453-2458.
Möller, S., & Forrest, S. R. (2002). Improved light out-coupling in organic light emitting diodes employing ordered microlens arrays. Journal of Applied Physics, 91(5), 3324-3327.
Sheriff Jr, H. K., Li, Y., Qu, B., & Forrest, S. R. (2021). Aperiodic optical coatings for neutral-color semi-transparent organic photovoltaics. Applied Physics Letters, 118(3), 033302.
Wang, B., Ruud, C. J., Price, J. S., Kim, H., & Giebink, N. C. (2019). Graded-index fluoropolymer antireflection coatings for invisible plastic optics. Nano letters, 19(2), 787-792.
Wang, B., Price, J. S., & Giebink, N. C. (2017). Durable broadband ultralow index fluoropolymer antireflection coatings for plastic optics. Optica, 4(2), 239-242.
Sobahan, K. M. A., Park, Y. J., Kim, J. J., & Hwangbo, C. K. (2011). Nanostructured porous SiO2 films for antireflection coatings. Optics Communications, 284(3), 873-876.
Tu, Min, Benzheng Xia, Dmitry E. Kravchenko, Max Lutz Tietze, Alexander John Cruz, Ivo Stassen, Tom Hauffman et al. “Direct X-ray and electron-beam lithography of halogenated zeolitic imidazolate frameworks.” Nature Materials 20, no. 1 (2021): 93-99.
Xomalis, Angelos, Caroline Hain, Alexander Groetsch, Fedor F. Klimashin, Thomas Nelis, Johann Michler, and Jakob Schwiedrzik. “Resist-Free E-beam Lithography for Patterning Nanoscale Thick Films on Flexible Substrates.” ACS Applied Nano Materials 6, no. 5 (2023): 3388-3394.

1. An organic light emitting device (OLED), comprising:
a substrate layer;
an external microlens array positioned below the substrate layer;
a graded antireflective coating comprising a plurality of sublayers, positioned on a surface of the external microlens array opposite the substrate layer;
a first electrode layer positioned over the substrate layer;
a light emitting layer positioned over the first electrode layer; and
a second electrode layer positioned over the light emitting layer.

2. The device of claim 1, wherein the light emitting layer comprises a first organics sublayer, an EML-organics sublayer positioned over the first organics sublayer, and a second organics sublayer positioned over the EML-organics sublayer.

3. The device of claim 1, wherein the external microlens array comprises a hexagonal-close packed array of hemispherical lenses.

4. The device of claim 1, wherein the graded antireflective coating comprises a low refractive index material.

5. The device of claim 1, wherein the graded antireflective coating comprises porous Teflon, Teflon or silicon dioxide.

6. The device of claim 1, wherein the external microlens array is adjacent to the substrate layer.

7. (canceled)

8. The device of claim 1, wherein the external microlens array has an index of refraction of 1.4 to 1.5.

9. The device of claim 1, wherein the device has an outcoupling efficiency of 30% to 40%.

10. The device of claim 1, wherein the device has an enhancement factor of 1.6 to 1.7.

11. The device of claim 1, wherein the plurality of sublayers in the graded antireflective coating comprises a 100 nm to 125 nm thick first sublayer with an index of refraction of 1.3 to 1.35, a 125 nm to 135 nm thick second sublayer below the first sublayer with an index of refraction of 1.15 to 1.25, and a 145 nm to 155 nm thick third sublayer below the second sublayer with an index of refraction of 1.0 to 1.1.

12. The device of claim 11, wherein the device has an outcoupling efficiency of 40% to 50%.

13. The device of claim 11, wherein the device has an enhancement factor of 1.75 to 1.85.

14. The device of claim 1, wherein the device has one or more characteristics selected from the group consisting of being flexible, being rollable, being foldable, being stretchable, being curved, being transparent, and being semi-transparent.

15. The device of claim 1, wherein the light emitting layer is configured to produce light via at least one of phosphorescence, fluorescence, thermally activated delayed fluorescence (TADF), phosphorescent delayed fluorescence, and triplet-triplet annihilation.

16. The device of claim 1, wherein the device comprises a 90 nm to 110 nm thick Al cathode, a 50 nm to 70 nm thick electron transport layer below the cathode with an index of refraction of 1.6 to 1.8, a 20 nm to 40 nm thick light emitting layer below the electron transport layer, a 20 nm to 30 nm thick hole transport layer below the light emitting layer with index of refraction of 1.6 to 1.8, a 140 nm to 160 nm thick ITO anode below the hole transport layer, and a semi-infinite microlens array below the anode with index of refraction of 1.4 to 1.5.

17. The device of claim 1, wherein at least one sublayer of the plurality of sublayers in the graded antireflective coating has a refractive index selected from the group consisting of: less than 1.35, less than 1.3, less than 1.25, less than 1.2, less than 1.15, less than 1.10, and less than 1.05.

18. The device of claim 1, wherein a first sublayer and a second sublayer of the plurality of sublayers are made of different materials;
wherein the first sublayer is closer to the external microlens array than the second sublayer; and
wherein the first sublayer has a higher refractive index than the second sublayer.

19. The device of claim 18, wherein the first or second sublayer has a refractive index between 1.05 and 1.3.

20. An organic light emitting device (OLED), comprising:
a substrate layer;
a first electrode layer positioned above the substrate layer;
a light emitting layer positioned above the first electrode layer; and
a second electrode layer positioned above the light emitting layer;
an external microlens array positioned over the second electrode layer; and
a graded antireflective coating comprising a plurality of sublayers, positioned on a surface of the external microlens array opposite the second electrode layer.

21. A method of manufacturing an organic light emitting device (OLED), comprising:
providing a substrate layer;
etching a sub-electrode microlens array (SEMLA) into the substrate layer;
depositing a first electrode layer over the substrate layer;
depositing a light emitting layer over the first electrode layer;
depositing a second electrode layer over the light emitting layer; and
depositing a graded antireflective coating on a surface of the sub-electrode microlens array opposite the substrate layer.

22.-23. (canceled)
